(19) United States
(12) Patent Application Publication
(10) Pub. No.: US 2026/0090243 A1
(43) Pub. Date: Mar. 26, 2026

(54) DISPLAY DEVICE AND ELECTRONIC DEVICE INCLUDING THE SAME

(71) Applicant: Samsung Display Co., LTD., Yongin-si (KR)

(72) Inventors: SANGHO LEE, Yongin-si (KR); YOONSEOK KA, Yongin-si (KR); YOOLGUK KIM, Yongin-si (KR)

(21) Appl. No.: 19/242,117

(22) Filed: Jun. 18, 2025

(30) Foreign Application Priority Data
Sep. 20, 2024 (KR) 10-2024-0127054

(51) Int. Cl. H10K 59/80; H10K 50/115; H10K 50/16; H10K 102/00

(52) U.S. Cl. CPC H10K 59/873; H10K 50/16; H10K 50/115; H10K 2102/351

(57) ABSTRACT

A display device includes: a substrate including a light emitting area and a non-light emitting area adjacent to the light emitting area, a circuit layer arranged on the substrate, a light emitting element arranged in the light-emitting area on the circuit layer and including: a first electrode, a light emitting layer including quantum dots and arranged on the first electrode, and a second electrode arranged on the light emitting layer, and an encapsulation layer arranged on the light emitting element and including: a first encapsulation layer including an organic material, an intermediate layer arranged on the first encapsulation layer including an organic acid, and a second encapsulation layer arranged on the intermediate layer and including an inorganic material.

This application claims priority to Korean Patent Application No. 10-2024-0127054, filed on Sep. 20, 2024, and all the benefits accruing therefrom under 35 U.S.C. § 119, the content of which in its entirety is herein incorporated by reference.

### BACKGROUND

### 1. Technical Field

Embodiments provide generally to a display device. More particularly, embodiments relate to a display device and an electronic device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

For example, an organic light emitting display device uses a self-luminous light emitting element which realizes display by emitting light from a light emitting material including an organic compound. Recently, development of light emitting element made of light emitting materials using quantum dots is in progress in order to improve color reproducibility of the display device.

### SUMMARY

Embodiments provide a display device with improved luminous efficiency.

Embodiments provide am electronic device including the display device.

A display device according to embodiments of the present disclosure includes: a first substrate including a light emitting area and a non-light emitting area adjacent to the light emitting area, a circuit layer arranged on the first substrate, a light emitting element arranged in the light-emitting area on the circuit layer and including: a first electrode, a light emitting layer including quantum dots and arranged on the first electrode, and a second electrode arranged on the light emitting layer, and an encapsulation layer arranged on the light emitting element and including: a first encapsulation layer including an organic material, an intermediate layer arranged on the first encapsulation layer including an organic acid, and a second encapsulation layer arranged on the intermediate layer and including an inorganic material.

In an embodiment, a thickness of the first encapsulation layer may be in a range of about 50 angstroms (Å) to about 500 angstroms (Å).

In an embodiment, the organic material of the first encapsulation layer may include at least one selected from a group consisting of silicone-based resin and acrylic-based resin.

In an embodiment, the first encapsulation layer may include a first sub-layer including an organic material and a second sub-layer arranged on the first sub-layer and including an inorganic material.

In an embodiment, the first sub-layer may be arranged between the light emitting element and the second sub-layer, and the second sub-layer may be arranged between the intermediate layer and the second encapsulation layer.

In an embodiment, the inorganic material of the second sub-layer may include a silicon compound.

In an embodiment, the intermediate layer may further include a polymer-based material.

In an embodiment, the encapsulation layer may further include an organic encapsulation layer arranged between the intermediate layer and the second encapsulation layer and including a polymer-based material.

In an embodiment, the organic acid of the intermediate layer may include at least one selected from a group consisting of polyacrylic acid (PAA), citric acid, isobutyric acid, and carboxylic acid.

In an embodiment, the inorganic material of the second encapsulation layer may include a silicon compound.

In an embodiment, the display device may further include a second substrate, which is an encapsulation substrate arranged on the encapsulation layer and including glass.

In an embodiment, the first electrode may be an anode electrode, the second electrode may be a cathode electrode, and the light emitting element may further include a hole transport layer arranged between the first electrode and the light emitting layer, a hole injection layer arranged between the first electrode and the hole transport layer, and an electron transport layer arranged between the light emitting layer and the second electrode.

In an embodiment, the electron transport layer may include inorganic particles including at least one selected from a group consisting of zinc oxide (ZnO) and zinc magnesium oxide (ZnMgO).

In an embodiment, the first electrode may be a cathode electrode, the second electrode may be an anode electrode, and the light emitting element may further include an electron transport layer arranged between the first electrode and the light emitting layer, a hole transport layer arranged between the light emitting layer and the second electrode, and a hole injection layer arranged between the light emitting layer and the hole transport layer.

In an embodiment, the electron transport layer may include inorganic particles including at least one selected from a group consisting of ZnO and ZnMgO.

An electronic device according to embodiments of the present disclosure includes: a display device, a power supply which supplies power to the display device, and a processor which controls the display device. The display device includes a substrate including a light emitting area and a non-light emitting area adjacent to the light emitting area, a circuit layer arranged on the substrate, a light emitting element arranged in the light-emitting area on the circuit layer and including: a first electrode, a light emitting layer including quantum dots and arranged on the first electrode, and a second electrode arranged on the light emitting layer, and an encapsulation layer arranged on the light emitting element and including: a first encapsulation layer including an organic material, an intermediate layer arranged on the first encapsulation layer including an organic acid, and a second encapsulation layer arranged on the intermediate layer and including an inorganic material.

In an embodiment, a thickness of the first encapsulation layer may be in a range of about 50 angstroms (Å) to about 500 angstroms (Å).

In an embodiment, the first encapsulation layer may include a first sub-layer including an organic material and a second sub-layer arranged on the first sub-layer and including an inorganic material, and the first sub-layer may be arranged between the light emitting element and the second sub-layer, and the second sub-layer may be arranged between the intermediate layer and the second encapsulation layer.

In an embodiment, the intermediate layer may further include a polymer-based material.

In an embodiment, the encapsulation layer may further include an organic encapsulation layer arranged between the intermediate layer and the second encapsulation layer and including a polymer-based material.

The display device according to embodiments of the present disclosure may include light emitting elements including a plurality of quantum dots, an encapsulation layer arranged on the light-emitting elements, and an encapsulation substrate arranged on the encapsulation layer and including glass. The encapsulation layer may include a first encapsulation layer including an organic material and having a thickness ranging from about 50 angstroms (Å) to about 500 angstroms (Å), an intermediate layer including both a polymer-based material and an organic acid, and a second encapsulation layer including an inorganic material arranged sequentially. Alternatively, the encapsulation layer may include an intermediate layer including an organic acid and an organic encapsulation layer including a polymer-based material sequentially arranged between the first encapsulation layer and the second encapsulation layer. Accordingly, damage to the light emitting elements may be minimized or reduced, and the lifespan characteristics of the light emitting elements may be excellent.

### BRIEF DESCRIPTION OF THE DRAWINGS

Illustrative, non-limiting embodiments will be more clearly understood from the following detailed description in conjunction with the accompanying drawings.

FIG. 1 is a perspective view showing a display device according to embodiments of the present disclosure.

FIG. 2 is an enlarged plan view of a portion of a display area of FIG. 1.

FIG. 3 is a cross-sectional view taken along line I-I′ of FIG. 2.

FIG. 4 is a cross-sectional view showing an example of a light emitting element.

FIG. 5 is a cross-sectional view showing another example of a light emitting element.

FIG. 6 is a cross-sectional view showing an example of an encapsulation layer of FIG. 3.

FIG. 7 is a cross-sectional view showing another example of an encapsulation layer of FIG. 3.

FIG. 8 is a cross-sectional view showing still another example of an encapsulation layer of FIG. 3.

FIG. 9 is a graph to explain normalized luminance over time in comparative examples and embodiments.

FIG. 10 is a block diagram showing an electronic device including the display device of FIG. 1.

FIG. 11 is a view illustrating an example in which the electronic device of FIG. 10 is implemented as a television.

### DETAILED DESCRIPTION

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

“About” or “substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value.

Hereinafter, a display device according to embodiments of the present disclosure will be explained in detail with reference to the accompanying drawings. The same reference numerals are used for the same components in the drawings, and redundant descriptions of the same components will be omitted.

In this specification, a plane may be defined as a first direction DR1 and a second direction DR2 intersecting the first direction DR1. For example, the first direction DR1 may be perpendicular to the second direction DR2. In addition, a third direction DR3 may be perpendicular to the plane.

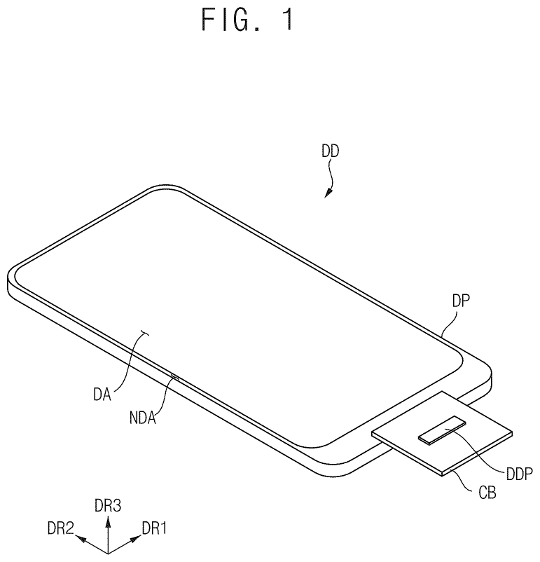

FIG. 1 is a perspective view showing a display device according to embodiments of the present disclosure.

Referring to FIG. 1, a display device DD according to embodiments of the present disclosure may include a display panel DP, a display driver DDP, and a circuit board CB.

The display panel DP may have a rectangular planar shape with a short side extending in the first direction DR1 and a long side extending in the second direction DR2. In this case, a corner where the short side and the long side of the display panel DP meet may be rounded to have a selected curvature or may be formed at a right angle. However, embodiments of the present disclosure are not necessarily limited to this, and the display panel DP may have a polygonal, circular, or oval planar shape in another embodiment.

The display panel DP may be formed to be flat. However, embodiments of the present disclosure are not limited to this, and the display panel DP may include a curved portion formed at the left and right ends and having a constant curvature or a changing curvature in another embodiment. In addition, the display panel DP may be flexible so that it can be bent, bent, folded, or rolled.

The display panel DP may include a display area DA and a non-display area NDA arranged around the display area DA. For example, when the display panel DP includes a curved portion, the display area DA may overlap the curved portion. In this case, the image of the display panel DP may be displayed even on the curved portion.

A plurality of sub-pixels may be arranged in the display area DA. Each of the sub-pixels may include a driving transistor, at least one switching transistor, at least one light emitting element, and at least one capacitor. The driving transistor supplies a driving current to the light emitting element according to a data voltage applied to a gate electrode, thereby allowing the light emitting element to emit light. The capacitor may serve to keep the data voltage applied to the gate electrode of the driving transistor constant.

The non-display area NDA may be defined as an area from the edge of the display area DA to the edge of the display panel DP. A scan driver which provides scan signals to the sub-pixels and pad electrodes may be arranged in the non-display area NDA. For example, the pad electrodes may be arranged on the lower edge of the display panel DP, and the scan driver may be arranged on the left and/or right edges of the display panel DP.

The display driver DDP may receive digital video data and timing signals from the outside. The display driver DDP may convert digital video data into analog positive/negative data voltages and provide the converted data voltages to data lines arranged in the display area DA. The display driver DDP may generate and supply a scan control signal for controlling the operation timing of the scan driver. In addition, the display driver DDP may supply a driving voltage to the sub-pixels.

For example, the display driver DDP may be formed as an integrated circuit (“IC”) and attached to the circuit board CB using a chip on film (“COF”) method. Alternatively, the display driver DDP may be directly attached to the display panel DP using a chip on glass (“COG”) method, a chip on plastic (“COP”) method, or an ultrasonic bonding method.

The circuit board CB may be attached to the pad electrodes. Specifically, the circuit board CB may be attached to the pad electrodes through an anisotropic conductive film. Accordingly, the circuit board CB may be electrically connected to the pad electrodes. For example, the circuit board CB may be a flexible printed circuit board (FPCB), a printed circuit board (PCB), or a flexible film such as a chip on film.

The display device DD may be any one of an organic light emitting display device, a liquid crystal display device, a plasma display device, a field emission display device, an electrophoretic display device, an electrowetting display device, a quantum dot light emitting display device, and a micro LED display device. In an embodiment, the display device DD may be a quantum dot light emitting display device.

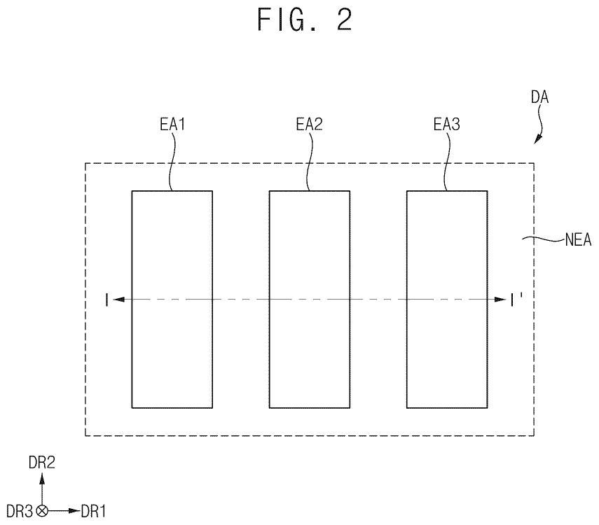

FIG. 2 is an enlarged plan view of a portion of a display area of FIG. 1.

Referring to FIG. 2, the display area DA may include a first light emitting area EA1, a second light emitting area EA2, a third light emitting area EA3, and a non-light emitting area NEA.

One sub-pixel may be arranged in each of the first light emitting area EA1, the second light emitting area EA2, and the third light emitting area EA3. Accordingly, each of the first light-emitting area EA1, the second light-emitting area EA2, and the third light-emitting area EA3 may be areas which emit light. The first light emitting area EA1 may emit light of a first color, the second light emitting area EA2 may emit light of a second color, and the third light emitting area EA3 may emit light of a third color. In an embodiment, the first color may be red, the second color may be green, and the third color may be blue. However, embodiments of the present disclosure are not necessarily limited thereto.

For example, the first light emitting area EA1, the second light emitting area EA2, and the third light emitting area EA3 may be repeatedly arranged along the first direction DR1. However, embodiments of the present disclosure are not necessarily limited to this, and the arrangement of the first light-emitting area EA1, the second light-emitting area EA2, and the third light-emitting area EA3 may be changed in various ways.

An area of the first light-emitting area EA1, an area of the second light-emitting area EA2, and an area of the third light-emitting area EA3 may be substantially the same. Alternatively, the area of the first light-emitting area EA1, the area of the second light-emitting area EA2, and the area of the third light-emitting area EA3 may be different from each other. However, embodiments of the present disclosure are not necessarily limited thereto.

The non-light emitting area NEA may surround the first light-emitting area EA1, the second light-emitting area EA2, and the third light-emitting area EA3. The non-light-emitting area NEA may be an area which does not emit light.

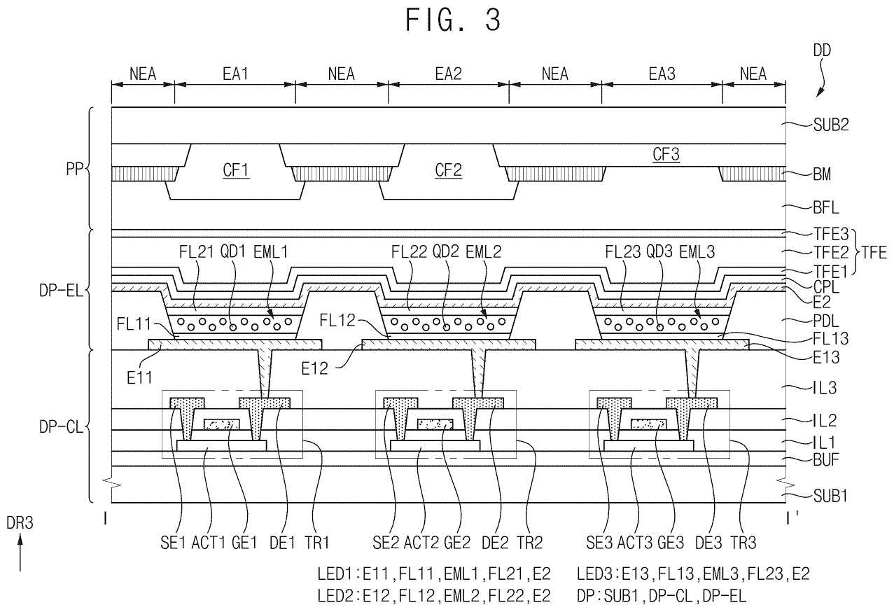

FIG. 3 is a cross-sectional view taken along line I-I′ of FIG. 2.

Referring to FIG. 3, the display device DD may include the display panel DP and an optical member PP. The display panel DP may include a first substrate SUB1, a circuit layer DP-CL, and a light emitting element layer DP-EL. The circuit layer DP-CL may include a buffer layer BUF, first, second, and third transistors TR1, TR2, and TR3, and first, second, and third insulating layers IL1, IL2, and IL3. The light emitting element layer DP-EL may include a pixel defining layer PDL, first, second, and third light emitting elements LED1, LED2, and LED3, a capping layer CPL, and an encapsulation layer TFE. In addition, the optical member PP may include a second substrate SUB2, first, second, and third color filters CF1, CF2, and CF3, a light blocking layer BM, and a protective layer BFL.

Here, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

In addition, the first light emitting element LED1 may include a first-first electrode E11, a first-first functional layer FL11, a first light emitting layer EML1, a second-first functional layer FL21, and a second electrode E2 sequentially stacked, the second light emitting element LED2 may include a first-second electrode E12, a first-second functional layer FL12, a second light emitting layer EML2, a second-second functional layer FL22, and the second electrode E2 sequentially stacked, and the third light emitting element LED3 may include a first-third electrode E13, a first-third functional layer FL13, a third light-emitting layer EML3, a second-third functional layer FL23, and the second electrode E2 sequentially stacked.

The first substrate SUB1 may include a glass substrate, a metal substrate, or a plastic substrate. However, embodiments of the present disclosure are not necessarily limited thereto. For another example, the first substrate SUB1 may include an inorganic layer, an organic layer, or a composite material layer. In addition, the first substrate SUB1 may include a flexible substrate with flexibility.

The buffer layer BUF may be arranged on the first substrate SUB1. The buffer layer BUF may prevent metal atoms or impurities from diffusing from the first substrate SUB1 to the first, second, and third transistors TR1, TR2, and TR3. In addition, the buffer layer BUF may improve the flatness of the surface of the first substrate SUB1 when the surface of the first substrate SUB1 is not uniform. For example, the buffer layer BUF may include an inorganic material such as silicon oxide, silicon nitride, silicon oxynitride, and the like. These can be used alone or in combination with each other.

The first, second, and third active patterns ACT1, ACT2, and ACT3 may be arranged on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor. In addition, the first, second, and third active patterns ACT1, ACT2, and ACT3 may be formed through the same process and may include the same material.

The metal oxide semiconductor may include indium (In), zinc (Zn), gallium (Ga), tin (Sn), titanium (Ti), aluminum (Al), hafnium (Hf), zirconium (Zr), magnesium (Mg), and the like containing binary compounds (ABₓ), ternary compounds (ABₓC_{y}), quaternary compounds (ABₓC_{y}D_{z}), and the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and the like. These can be used alone or in combination with each other.

Each of the first, second, and third active patterns ACT1, ACT2, and ACT3 may include a source region, a drain region, and a channel region located between the source region and the drain region. The source region and the drain region may be doped with impurities (e.g., n-type impurities or p-type impurities), and the channel region may be a region which is not doped with impurities.

The first insulating layer IL1 may be arranged on the buffer layer BUF. The first insulating layer IL1 may sufficiently cover the first, second, and third active patterns ACT1, ACT2, and ACT3, and may have a substantially flat upper surface without creating steps around the first, second, and third active patterns ACT1, ACT2, and ACT3. Alternatively, the first insulating layer IL1 may cover the first, second, and third active patterns ACT1, ACT2, and ACT3, and may be arranged along the profiles of each of the first, second, and third active patterns ACT1, ACT2, and ACT3 with a uniform thickness. For example, the first insulating layer IL1 may include an inorganic material such as silicon oxide (SiOₓ), silicon nitride (SiNₓ), silicon carbide (SiCₓ), silicon oxynitride (SiOₓN_{y}), and the like. These can be used alone or in combination with each other.

The first, second, and third gate electrodes GE1, GE2, and GE3 may be arranged on the first insulating layer IL1. The first gate electrode GE1 may overlap the channel area of the first active pattern ACT1, the second gate electrode GE2 may overlap the channel area of the second active pattern ACT2, and the third gate electrode GE3 may overlap the channel area of the third active pattern ACT3 in a plan view.

Each of the first, second, and third gate electrodes GE1, GE2, and GE3 may include metal, alloy metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide include indium tin oxide, indium zinc oxide, and the like. In addition, examples of the metal nitride include aluminum nitride (AlNₓ), tungsten nitride (WNₓ), chromium nitride (CrNₓ), and the like. These can be used alone or in combination with each other.

The first, second, and third gate electrodes GE1, GE2, and GE3 may be formed through the same process and may include the same material.

The second insulating layer IL2 may be arranged on the first insulating layer IL1. The second insulating layer IL2 may sufficiently cover the first, second, and third gate electrodes GE1, GE2, and GE3, and may have a substantially flat upper surface without creating steps around the first, second, and third gate electrodes GE1, GE2, and GE3. Alternatively, the second insulating layer IL2 may cover the first, second, and third gate electrodes GE1, GE2, and GE3, and may be arranged along the profile of each of the first, second, and third gate electrodes GE1, GE2, and GE3 with a uniform thickness. For example, the second insulating layer IL2 may include an inorganic material such as silicon oxide, silicon nitride, silicon carbide, silicon oxynitride, and the like. These can be used alone or in combination with each other.

The first, second, and third source electrodes SE1, SE2, and SE3 may be arranged on the second insulating layer IL2. The first source electrode SE1 may be connected to the source region of the first active pattern ACT1 through a contact hole penetrating the first and second insulating layers IL1 and IL2. The second source electrode SE2 may be connected to the source region of the second active pattern ACT2 through a contact hole penetrating the first and second insulating layers IL1 and IL2. The third source electrode SE3 may be connected to the source region of the third active pattern ACT3 through a contact hole penetrating the first and second insulating layers IL1 and IL2.

The first, second, and third drain electrodes DE1, DE2, and DE3 may be arranged on the second insulating layer IL2. The first drain electrode DE1 may be connected to the drain region of the first active pattern ACT1 through a contact hole penetrating the first and second insulating layers IL1 and IL2. The second drain electrode DE2 may be connected to the drain region of the second active pattern ACT2 through a contact hole penetrating the first and second insulating layers IL1 and IL2. The third drain electrode DE3 may be connected to the drain region of the third active pattern ACT3 through a contact hole penetrating the first and second insulating layers IL1 and IL2.

For example, each of the first, second, and third source electrodes SE1, SE2, and SE3 may include metal, alloy, metal nitride, conductive metal oxide, transparent conductive material, and the like. These can be used alone or in combination with each other. The first, second, and third drain electrodes DE1, DE2, and DE3 may be formed through the same process as the first, second, and third source electrodes SE1, SE2, and SE3, and may include the same material as the first, second, and third source electrodes SE1, SE2, and SE3.

The third insulating layer IL3 may be arranged on the second insulating layer IL2. The third insulating layer IL3 may sufficiently cover the first, second, and third source electrodes SE1, SE2, and SE3 and the first, second, and third drain electrodes DE1, DE2, and DE3. That is, the third insulating layer IL3 may be a planarization layer. The third insulating layer IL3 may include an organic material. For example, the third insulating layer IL3 may include organic materials such as phenolic resin, polyacrylates resin, polyimides resin, polyamides resin, siloxane resin, epoxy resin, and the like. These can be used alone or in combination with each other.

The first-first, first-second, and first-third electrodes E11, E12, and E13 may be arranged on the third insulating layer IL3. The first-first electrode E11 may overlap the first light emitting area EA1, the first-second electrode E12 may overlap the second light emitting area EA2, and the first-third electrode E13 may overlap the third light emitting area EA3 in a plan view. The first-first electrode E11 may be connected to the first drain electrode DE1 (or the first source electrode SE1) through a contact hole penetrating the third insulating layer IL3, the first-second electrode E12 may be connected to the second drain electrode DE2 (or the second source electrode SE2) through a contact hole penetrating the third insulating layer IL3. In addition, the first-third electrode E13 may be connected to the third drain electrode DE3 (or the third source electrode SE3) through a contact hole penetrating the third insulating layer IL3.

Each of the first-first, first-second, and first-third electrodes E11, E12, and E13 may be a transmissive electrode, a semi-transmissive electrode, or a reflective electrode. For example, each of the first-first, first-second, and first-third electrodes E11, E12, and E13 may include metal, alloy, metal nitride, conductive metal oxide, transparent conductive material, and the like. These can be used alone or in combination with each other.

The first-first, first-second, and first-third electrodes E11, E12, and E13 may be formed through the same process and may include the same material.

In an embodiment, each of the first-first, first-second, and first-third electrodes E11, E12, and E13 may be an anode electrode. In another embodiment, each of the first-first, first-second, and first-third electrodes E11, E12, and E13 may be a cathode electrode.

For example, as shown in FIG. 3, the first-first, first-second, and first-third electrodes E11, E12, and E13 may be patterned to correspond to the first, second, and third light emitting areas EA1, EA2, and EA3, respectively. Alternatively, the first-first, first-second, and first-third electrodes E11, E12, and E13 may be formed integrally and provided as one common layer.

The pixel defining layer PDL may be arranged on the third insulating layer IL3. The pixel defining layer PDL may overlap the non-light emitting area NEA in a plan view. A pixel opening exposing at least a portion of an upper surface of each of the first-first, first-second, and first-third electrodes E11, E12, and E13 may be defined in the pixel defining layer PDL. The pixel defining layer PDL may include an inorganic material and/or an organic material. For example, the pixel defining layer PDL may include an organic material such as epoxy resin, siloxane resin, and the like. These can be used alone or in combination with each other. Alternatively, the pixel defining layer PDL may include an inorganic material and/or an organic material containing a light blocking material such as black pigment, black dye, and the like.

The first-first functional layer FL11 may be arranged on the first-first electrode E11, the first-second functional layer FL12 may be arranged on the first-second electrode E12, and the first-third functional layer FL13 may be arranged on the first-third electrode E13. The first-first functional layer FL11 may overlap the first light-emitting area EA1, the first-second functional layer FL12 may overlap the second light-emitting area EA2, and the first-third functional layer FL13 may overlap the third light-emitting area EA3 in a plan view. Specifically, the first-first, first-second, and first-third functional layers FL11, FL12, and FL13 may be arranged in the pixel opening of the pixel defining layer PDL, respectively.

Taking as an example the case where the first-first, first-second, and first-third electrodes E11, E12, and E13 are anode electrodes and the second electrode E2 is a cathode electrode, the components of each of the first-first, first-second, and first-third functional layers FL11, FL12, and FL13 will be described.

Each of the first-first, first-second, and first-third functional layers FL11, FL12, and FL13 may include a hole transport layer. The hole transport layer may serve to facilitate the injection of holes from the first electrode (e.g., the first-first electrode E11, the first-second electrode E12, or the first-third electrode E13) to the light emitting layer (e.g., the first light emitting layer EML1, the second light emitting layer EML2, or the third light emitting layer EML3).

For example, the hole transport layer may include carbazole-based derivatives such as N-phenylcarbazole and polyvinylcarbazole, fluorene-based derivatives, TPD (N,N′-bis(3-methylphenyl)-N,N′-diphenyl-[1,1-biphenyl]-4,4′-diamine), triphenylamine derivatives such as TCTA(4,4′,4″-tris(N-carbazolyl)triphenylamine), NPD(N,N′-di(naphthalene-1-yl)-N,N′-diphenyl-benzidine), TAPC (4,4′-Cyclohexylidenebis[N,Nbis(4-methylphenyl)benzenamine]), HMTPD(4,4′-Bis[N,N′-(3-tolyl)amino]-3,3′-dimethylbiphenyl), mCP(1,3-Bis (N-carbazolyl)benzene), and the like. However, embodiments of the present disclosure are not necessarily limited thereto.

Each of the first-first, first-second, and first-third functional layers FL11, FL12, and FL13 may further include a hole injection layer in addition to the hole transport layer. In this case, the hole injection layer may be arranged between each of the first-first, first-second, and first-third functional layers FL11, FL12, and FL13 and the hole injection layer. The hole injection layer may improve hole injection characteristics into the hole transport layer without increasing the driving voltage. For example, the hole injection layer may include common materials known in the art.

For example, as shown in FIG. 3, the first-first, first-second, and first-third functional layers FL11, FL12, and FL13 may be arranged to be spaced apart from each other. Alternatively, the first-first, first-second, and first-third functional layers FL11, FL12, and FL13 may be formed integrally and provided as one common layer.

In an embodiment, the first-first, first-second, and first-third functional layers FL11, FL12, and FL13 may be formed through an inkjet printing process.

The first light emitting layer EML1 may be arranged on the fir electrode (E11), the second light emitting layer EML2 may be arranged on the first-second electrode E12, and the third light emitting layer EML3 may be arranged on the first-third electrode E13. The first light emitting layer EML1 may overlap the first light emitting area EA1, the second light emitting layer EML2 may overlap the second light emitting area EA2, and the third light emitting layer EML3 may overlap the third light emitting area EA3 in a plan view. Specifically, the first, second, and third light emitting layers EML1, EML2, and EML3 may be arranged in the pixel opening of the pixel defining layer PDL.

In an embodiment, the first light-emitting layer EML1 may include a plurality of first quantum dots QD1, the second light-emitting layer EML2 may include a plurality of second quantum dots QD2, and the third light-emitting layer EML3 may include a plurality of third quantum dots QD3. For example, the first quantum dots QD1 may emit light of a first color, the second quantum dots QD2 may emit light of a second color, and the third quantum dots QD3 may emit light of a third color.

For example, the first color light may be red light, the second color light may be green light, and the third color light may be blue light.

For example, the first, second, and third quantum dots QD1, QD2, and QD3 may include a group II-VI compound, a group III-V compound, a group IV-VI compound, a group IV element, a group IV compound, and the like. These can be used alone or in combination with each other.

For example, each of the first, second, and third quantum dots QD1, QD2, and QD3 may have a core-shell structure including a core and a shell surrounding the core. The shell serves as a protective layer to maintain semiconductor properties by preventing chemical denaturation of the core, and may serve as a charging layer to impart electrophoretic properties to the first, second, and third quantum dots QD1, QD2, and QD3.

In an embodiment, the first, second, and third light emitting layers EML1, EML2, and EML3 may be formed through an inkjet printing process.

The second-first functional layer FL21 may be arranged on the first light emitting layer EML1, the second-second functional layer FL22 may be arranged on the second light emitting layer EML2, and the second-third functional layer FL23 may be arranged on the third light emitting layer EML3. The second-first functional layer FL21 may overlap the first light emitting area EA1, the second-second functional layer FL22 may overlap the second light emitting area EA2, and the second-third functional layer FL23 may overlap the third light emitting area EA3 in a plan view. Specifically, the second-first, second-second, and second-third functional layers FL21, FL22, and FL23 may be arranged in the pixel opening of the pixel defining layer PDL.

Taking as an example the case where the first-first, first-second, and first-third electrodes E11, E12, and E13 are cathode electrodes and the second electrode E2 is an anode electrode, the components of each of the second-first, second-second, and second-third functional layers FL21, FL22, and FL23 will be described.

Each of the second-first, second-second, and second-third functional layers FL21, FL22, and FL23 may include an electron transport layer. The electron transport layer may transfer electrons from the second electrode E2 to the light emitting layer.

For example, the electron transport layer may include inorganic particles, peroxides, hydrocarbon compounds, and solvents. The inorganic particles may serve to transport electrons injected from the second electrode E2. The inorganic particles may include metal oxide. For example, the metal oxide may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, Y₂O₃, and the like or ZnMgO, MgAl₂O₄, or ternary compounds such as CoFe₂O₄, NiFe₂O₄, CoMn₂O₄, BaTiO₃, BaZrO₃, ZrSiO₄, and the like. These can be used alone or in combination with each other. In an embodiment, the electron transport layer may include ZnO, ZnMgO, and the like.

Each of the second-first, second-second, and second-third functional layers FL21, FL22, and FL23 may further include an electron injection layer in addition to the electron transport layer. In this case, the electron injection layer may be arranged between the second electrode E2 and the electron transport layer. The electron injection layer may improve electron injection characteristics into the electron transport layer without increasing the driving voltage.

For example, as shown in FIG. 3, the second-first, second-second, and second-third functional layers FL21, FL22, and FL23 may be arranged to be spaced apart from each other. Alternatively, the second-first, second-second, and second-third functional layers FL21, FL22, and FL23 may be formed integrally and provided as one common layer.

In an embodiment, the second-first, second-second, and second-third functional layers FL21, FL22, and FL23 may be formed through an inkjet printing process.

The second electrode E2 may be arranged on the second-first, second-second, and second-third functional layers FL21, FL22, and FL23. The second electrode E2 may be a transmissive electrode, a semi-transmissive electrode, or a reflective electrode. For example, the second electrode E2 may include metal, alloy, metal nitride, conductive metal oxide, transparent conductive material, and the like. These can be used alone or in combination with each other.

In an embodiment, the second electrode E2 may be a cathode electrode. In another embodiment, the second electrode E2 may be an anode electrode.

In an embodiment, the second electrode E2 may be formed integrally and provided as one common layer. That is, the second electrode E2 may be commonly arranged in the first, second, and third light emitting areas EA1, EA2, and EA3 and the non-light emitting area NEA.

The capping layer CPL may be arranged on the second electrode E2. The capping layer CPL may cover the first, second, and third light emitting elements LED1, LED2, and LED). The capping layer CPL may be commonly arranged in the first, second, and third light emitting areas EA1, EA2, and EA3 and the non-light emitting area NEA. The capping layer CPL may improve viewing angle characteristics and increase external light emitting efficiency.

The capping layer CPL may include an organic material and/or an inorganic material having light transparency. That is, the capping layer CPL may be composed of an inorganic layer, an organic layer, or an organic layer including inorganic particles. For example, the capping layer CPL may include a triamine derivative, carbazole biphenyl derivative, arylenediamine derivative, aluminum quinoleum complex (Alq₃), and the like. These can be used alone or in combination with each other. However, embodiments of the present disclosure are not necessarily limited thereto.

The encapsulation layer TFE may be arranged on the capping layer CPL. The encapsulation layer TFE may be commonly arranged in the first, second, and third light emitting areas EA1, EA2, and EA3 and the non-light emitting area NEA.

The encapsulation layer TFE may cover the first, second, and third light emitting elements LED1, LED2, and LED3. The encapsulation layer TFE may include at least one inorganic layer and at least one organic layer. The inorganic layer of the encapsulation layer TFE may protects the first, second, and third light emitting elements LED1, LED2, and LED3 from external moisture, and the organic layer of the encapsulation layer TFE may prevent the first, second, and third light emitting elements LED1, LED2, and LED3 from being damaged by foreign substances introduced during the manufacturing process.

For example, the encapsulation layer TFE may include a first encapsulation layer TFE1, an intermediate layer TFE2, and a second encapsulation layer TFE3 sequentially stacked. A detailed description of the first encapsulation layer TFE1, the intermediate layer TFE2, and the second encapsulation layer TFE3 will be described later.

The optical member PP may be arranged on the encapsulation layer TFE. The optical member PP may block external light provided to the display panel DP from outside the display panel DP. That is, the optical member PP may perform an anti-reflection function which minimizes reflection by external light. Hereinafter, the configurations of the optical member PP will be described.

The second substrate SUB2 may include a glass substrate, a metal substrate, or a plastic substrate. In an embodiment, the second substrate SUB2 may include a glass substrate. However, embodiments of the present disclosure are not necessarily limited thereto. For another example, the second substrate SUB2 may include an inorganic layer, an organic layer, or a composite material layer. The second substrate SUB2 may be referred to as an “encapsulation substrate”.

A sealant may be arranged between the first substrate SUB1 and the second substrate SUB2. The sealant may be arranged in the non-display area NDA of FIG. 1. The sealant may surround the display area DA of FIG. 1 and prevent moisture from penetrating through the side surfaces.

The first, second, and third color filters CF1, CF2, and CF3 may be arranged under the second substrate SUB2. The first, second, and third color filters CF1, CF2, and CF3 may selectively transmit light of a specific wavelength.

The first color filter CF1 may transmit light of the first color (e.g., red light). For example, the first color filter CF1 may include red pigment or dye. The second color filter CF2 may transmit light of the second color (e.g., green light). For example, the second color filter CF2 may include green pigment or dye. The third color filter CF3 may transmit the third color light (e.g., blue light). For example, the third color filter CF3 may include blue pigment or dye. However, embodiments of the present disclosure are not limited thereto.

For example, the third color filter CF3 may partially overlap the first color filter CF1 and the second color filter CF2 in a plan view. However, embodiments of the present disclosure are not necessarily limited to this. In another embodiment, the first, second, and third color filters CF1, CF2, and CF3 do not overlap each other in the plan view, and the first, second, and third color filters CF1, CF2, and CF3 may be arranged to overlap the first, second, and third light emitting areas EA1, EA2, and EA3, respectively. Alternatively, the first, second, and third color filters CF1, CF2, and CF3 may be omitted.

The light blocking layer BM may be arranged under the first, second, and third color filters CF1, CF2, and CF3. The light blocking layer BM may overlap the non-light emitting area NEA in a plan view. The light blocking layer BM may be a black matrix. For example, the light blocking layer BM may include an organic light blocking material or an inorganic light blocking material containing black pigment or black dye. The light blocking layer BM prevents light leakage and may distinguish boundaries between the adjacent first, second, and third color filters CF1, CF2, and CF3.

The protective layer BFL may be arranged under the light blocking layer BM and the first, second, and third color filters CF1, CF2, and CF3. The protective layer BFL may cover the light blocking layer BM and the first, second, and third color filters CF1, CF2, and CF3. The protective layer BFL may protect the first, second, and third color filters CF1, CF2, and CF3. For example, the protective layer BFL may include a silicon compound such as silicon oxide, silicon nitride, silicon oxynitride, and the like. These can be used alone or in combination with each other.

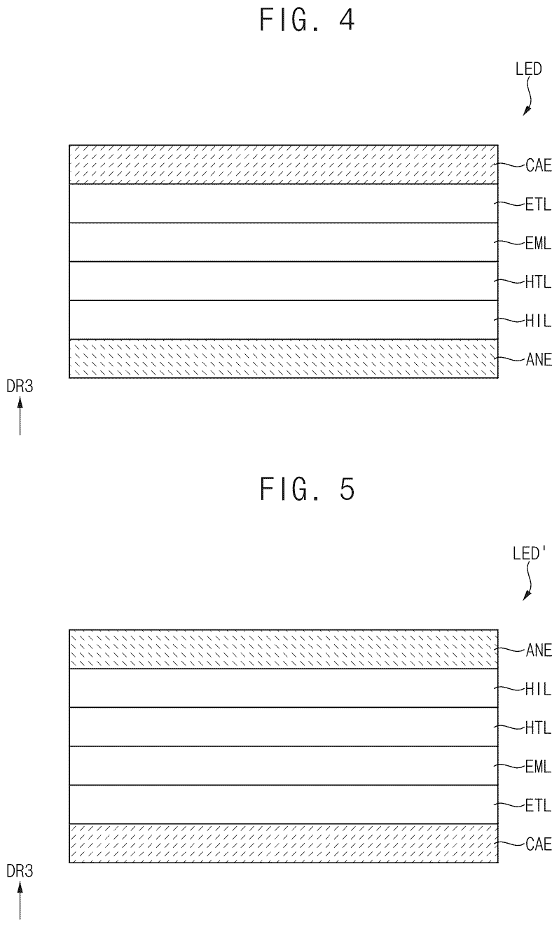

FIG. 4 is a cross-sectional view showing an example of a light emitting element.

Referring to FIG. 4, the light emitting element LED may include an anode electrode ANE, a hole injection layer HIL, a hole transport layer HTL, a light emitting layer EML, an electron transport layer ETL, and a cathode electrode CAE sequentially stacked along the third direction DR3. In this case, the light emitting layer EML may include quantum dots and may emit light along the third direction DR3.

In an embodiment, each of the first, second, and third light emitting elements LED1, LED2, and LED3 of FIG. 3 may have the same structure as the light emitting element LED of FIG. 4. In this case, each of the first-first, first-second, and first-third electrodes E11, E12, and E13 of FIG. 3 may correspond to the anode electrode ANE, each of the first-first, first-second, and first-third functional layers FL11, FL12, and FL13 of FIG. 3 may correspond to the hole injection layer HIL and the hole transport layer HTL, each of the second-first, second-second, and second-third functional layers FL21, FL22, and FL23 may correspond to the electron transport layer ETL, and the second electrode E2 of FIG. 3 may correspond to the cathode electrode CAE.

FIG. 5 is a cross-sectional view showing another example of a light emitting element.

Referring to FIG. 5, the light emitting element LED′ may include a cathode electrode CAE, an electron transport layer ETL, a light emitting layer EML, a hole transport layer HTL, a hole injection layer HIL, and an anode electrode ANE sequentially stacked along the third direction DR3. In this case, the light emitting layer EML may include quantum dots and may emit light along the third direction DR3.

In an embodiment, each of the first, second, and third light emitting elements LED1, LED2, and LED3 of FIG. 3 may have the same structure as the light emitting element LED′ of FIG. 5. In this case, each of the first-first, first-second, and first-third electrodes E11, E12, and E13 of FIG. 3 may be correspond to the cathode electrode CAE, each of the first-first, first-second, and first-third functional layers FL11, FL12, and FL13 of FIG. 3 may be correspond to the electron transport layer ETL, each of the second-first, second-second, and second-third functional layers FL21, FL22, and FL23 may correspond to the hole transport layer HTL and the hole injection layer HIL, and the second electrode E2 of FIG. 3 may correspond to the anode electrode ANE.

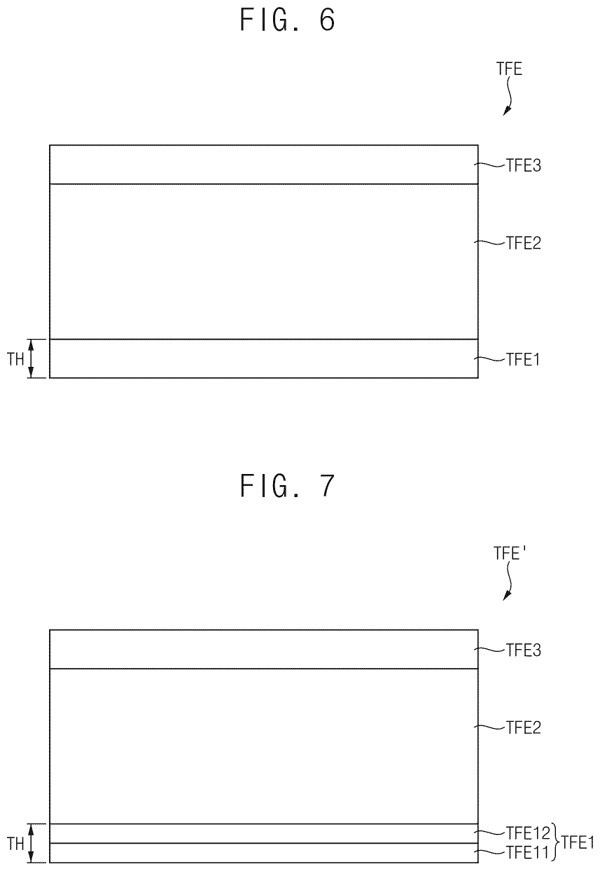

FIG. 6 is a cross-sectional view showing an example of an encapsulation layer of FIG. 3.

Referring to FIG. 6, as described above, the encapsulation layer TFE may include the first encapsulation layer TFE1, the intermediate layer TFE2, and the second encapsulation layer TFE3 sequentially arranged along the third direction DR3.

In an embodiment, the first encapsulation layer TFE1 may include an organic material. In this case, compared to the case where the first encapsulation layer TFE1 includes only an inorganic material, damage to the first, second, and third light emitting elements LED1, LED2, and LED3 may be minimized or reduced. For example, the first encapsulation layer TFE1 may include an organic material such as silicone-based resin (e.g., silicon oxycarbide (SiOC)), acrylic resin, and the like. These can be used alone or in combination with each other. However, embodiments of the present disclosure are not necessarily limited thereto, and the first encapsulation layer TFE1 may include various organic materials.

In an embodiment, the thickness TH of the first encapsulation layer TFE1 may be in a range of about 50 angstroms (Å) to about 500 angstroms (Å). Preferably, the thickness TH of the first encapsulation layer TFE1 may be in a range of about 100 angstroms (Å) to about 500 angstroms (Å). If the thickness TH of the first encapsulation layer TFE1 is less than about 50 angstroms (Å), damage may occur in the first, second, and third light emitting elements LED1, LED2, and LED3. When the thickness TH of the first encapsulation layer TFE1 exceeds about 500 angstroms (Å), the positive aging effect may be minimized or reduced.

Here, the positive aging effect refers to a phenomenon in which efficiency temporarily increases over time when driving a light emitting element.

The intermediate layer TFE2 may include an organic material. In an embodiment, the intermediate layer TFE2 may include both a polymer-based material and an organic acid. For example, examples of the polymer-based material include acrylic resin, epoxy-based resin, polyimide-based resin, and polyethylene-based resin. In addition, examples of the organic acid may include polyacrylic acid (“PAA”), citric acid, isobutyric acid, carboxylic acid, and the like. These can be used alone or in combination with each other.

The organic acid may diffuse (or be dispersed) from the intermediate layer TFE2. The organic acid diffused (or dispersed) from the intermediate layer TFE2 may reach the first, second, and third light emitting elements LED1, LED2, and LED3. Accordingly, the positive aging effect of the first, second, and third light emitting elements LED1, LED2, and LED3 may be effectively promoted.

The second encapsulation layer TFE3 may include an inorganic material. The second encapsulation layer TFE3 may include a silicon compound and/or metal oxide. For example, the second encapsulation layer TFE3 may include silicon oxide, silicon nitride, silicon oxynitride, aluminum oxide, titanium oxide, tantalum oxide, hafnium oxide, zinc oxide, and the like. These can be used alone or in combination with each other.

FIG. 7 is a cross-sectional view showing another example of an encapsulation layer of FIG. 3.

Referring to FIG. 7, as described above, the encapsulation layer TFE′ may include the first encapsulation layer TFE1, the intermediate layer TFE2, and the second encapsulation layer TFE3 sequentially arranged along the third direction DR3. Hereinafter, elements that overlap with those described with reference to FIGS. 3 and 6 will be omitted or simplified.

In an embodiment, the first encapsulation layer TFE1 may include an organic-inorganic composite film including an organic material and an inorganic material. Specifically, the first encapsulation layer TFE1 may include a first sub-layer TFE11 including an organic material and a second sub-layer TFE12 arranged on the first sub-layer TFE11 and including an inorganic material. That is, the first sub-layer TFE11 may be arranged between the first to third light-emitting elements LED1, LED2, and LED3 of FIG. 3 and the second sub-layer TFE12, and the second sub-layer TFE12 may be arranged between the intermediate layer TFE2 and the second encapsulation layer TFE3.

For example, the first sub-layer TFE111 may include an organic material such as silicone-based resin (e.g., silicon oxycarbide (SiOC)), acrylic resin, and the like. These can be used alone or in combination with each other. However, embodiments of the present disclosure are not necessarily limited thereto, and the first sub-layer TFE11 may include various organic materials.

The second sub-layer TFE11 may include an inorganic material such as a silicon compound. For example, the second sub-layer TFE11 may include an inorganic material such as silicon oxide, silicon nitride, silicon oxynitride, and the like. These can be used alone or in combination with each other.

The intermediate layer TFE2 may include an organic material. In an embodiment, the intermediate layer TFE2 may include both a polymer-based material and an organic acid. The second encapsulation layer TFE3 may include an inorganic material. The second encapsulation layer TFE3 may include a silicon compound and/or metal oxide.

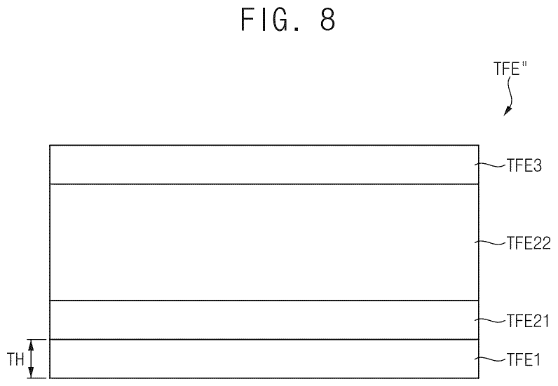

FIG. 8 is a cross-sectional view showing still another example of an encapsulation layer of FIG. 3.

Referring to FIG. 8, as described above, the encapsulation layer TFE″ may include the first encapsulation layer TFE1, an intermediate layer TFE21, an organic encapsulation layer TFE22, and the second encapsulation layer TFE3 sequentially arranged along the third direction DR3. Hereinafter, elements that overlap with those described with reference to FIGS. 3 and 6 will be omitted or simplified.

In an embodiment, the first encapsulation layer TFE1 may include an organic material. For example, the first encapsulation layer TFE1 may include an organic material such as silicone-based resin (e.g., silicon oxycarbide (SiOC)), acrylic resin, and the like. However, embodiments of the present disclosure are not necessarily limited to this, and as shown in FIG. 7, the first encapsulation layer TFE1 may include an organic-inorganic composite film including an organic material and an inorganic material.

In an embodiment, the intermediate layer TFE21 may include an organic acid. The organic acid may diffuse (or disperse) from the intermediate layer TFE21. The organic acid diffused (or dispersed) from the intermediate layer TFE21 may reach the first, second, and third light emitting elements LED1, LED2, and LED3. Accordingly, the positive aging effect of the first, second, and third light emitting elements LED1, LED2, and LED3 may be effectively promoted.

The organic encapsulation layer TFE22 may include a polymer-based material. In addition, the second encapsulation layer TFE2 may include a silicon compound and/or metal oxide.

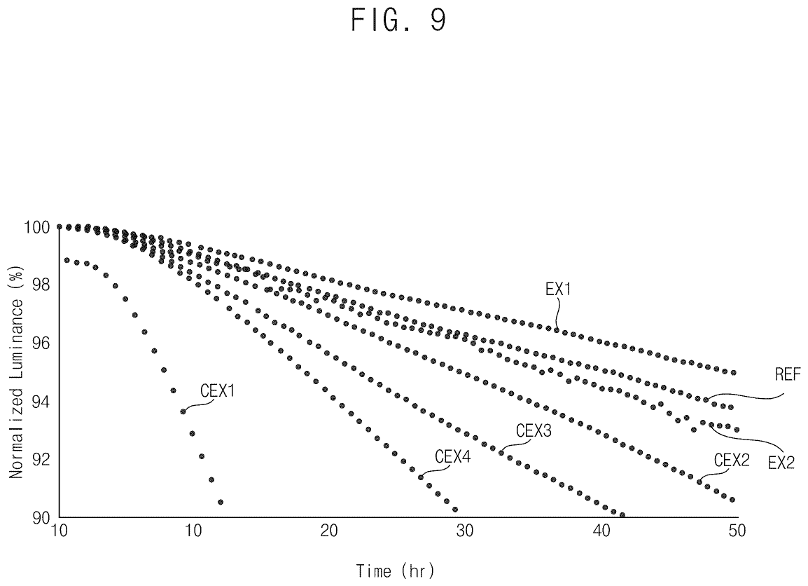

FIG. 9 is a graph to explain normalized luminance over time in comparative examples and embodiments.

Referring to FIG. 9, in comparative examples and embodiments, normalized luminance over time when driving the light emitting element was compared.

In a comparative example 1 (CEX1), a display device was manufactured including a light emitting element including a plurality of quantum dots and an encapsulation substrate including glass on the light emitting element. That is, the display device satisfying the comparative example 1 (CEX1) does not include the encapsulation layer TFE as shown in FIG. 3. In addition, a resin layer containing an organic acid such as polyacrylic acid was not applied to the lower surface of the encapsulation substrate of the display device satisfying the comparative example 1 (CEX1).

In a comparative example 2 (CEX2), a display device was manufactured including a light emitting element including a plurality of quantum dots, an encapsulation layer on the light emitting element, and an encapsulation substrate including glass on the encapsulation layer. As shown in FIG. 7, the encapsulation layer includes a first encapsulation layer including an organic-inorganic composite film containing SiOC and SiON, an intermediate layer including both an acrylic resin and polyacrylic acid, and a second encapsulation layer including a common silicon compound known in the art. In this case, the thickness of the first encapsulation layer was about 700 angstroms (Å).

In a comparative example 3 (CEX3), a display device was manufactured including a light emitting element including a plurality of quantum dots, an encapsulation layer on the light emitting element, and an encapsulation substrate including glass on the encapsulation layer. As shown in FIG. 7, the encapsulation layer includes a first encapsulation layer including an organic-inorganic composite film containing SiOC and SiON, an intermediate layer including both an acrylic resin and polyacrylic acid, and a second encapsulation layer including a common silicon compound known in the art. In this case, the thickness of the first encapsulation layer was about 900 angstroms (Å).

In a comparative example 4 (CEX4), a display device was manufactured including a light emitting element including a plurality of quantum dots, an encapsulation layer on the light emitting element, and an encapsulation substrate including glass on the encapsulation layer. As shown in FIG. 7, the encapsulation layer includes a first encapsulation layer including an organic-inorganic composite film containing SiOC and SiON, an intermediate layer including both an acrylic resin and polyacrylic acid, and a second encapsulation layer including a common silicon compound known in the art. In this case, the thickness of the first encapsulation layer was about 15000 angstroms (Å).

In REF, a display device was manufactured including a light emitting element including a plurality of quantum dots, an encapsulation substrate including glass on the light emitting element, and a resin layer including polyacrylic acid applied to the lower surface of the encapsulation substrate. That is, the display device satisfying the REF does not include the encapsulation layer TFE as shown in FIG. 3.

Referring further to FIGS. 3 and 7, in an embodiment 1 (EX1), the display device DD was manufactured including a light emitting elements (e.g., the first, second, and third light emitting elements LED1, LED2, and LED3) including a plurality of quantum dots, the encapsulation layer TFE′ on the light-emitting element, and the encapsulation substrate SUB2 including glass on the encapsulation layer TFE′. As shown in FIG. 7, the encapsulation layer TFE′ includes the first encapsulation layer TFE1 including an organic-inorganic composite film including SiOC and SiON, the intermediate layer TFE2 including both an acrylic resin and polyacrylic acid, and the second encapsulation layer TFE3 including a common silicon compound known in the art. In this case, the thickness TH of the first encapsulation layer TFE1 was about 250 angstroms (Å).

In an embodiment 2 (EX2), the display device DD was manufactured including a light emitting elements (e.g., the first, second, and third light emitting elements LED1, LED2, and LED3) including a plurality of quantum dots, the encapsulation layer TFE′ on the light-emitting element, and the encapsulation substrate SUB2 including glass on the encapsulation layer TFE′. As shown in FIG. 7, the encapsulation layer TFE′ includes the first encapsulation layer TFE1 including an organic-inorganic composite film including SiOC and SiON, the intermediate layer TFE2 including both an acrylic resin and polyacrylic acid, and the second encapsulation layer TFE3 including a common silicon compound known in the art. In this case, the thickness TH of the first encapsulation layer TFE1 was about 500 angstroms (Å).

As a result, it can be confirmed that the slope of the decrease in normalized luminance over time when driving the light emitting element of the display device DD satisfying the embodiment 1 (EX1) and the embodiment 2 (EX2) is substantially similar to the slope of decrease in normalized luminance over time of the display device satisfying the REF. On the other hand, it can be confirmed that the slope of the decrease in normalized luminance over time when driving the light emitting element of the display device satisfying the comparative example 1 (CEX1), the comparative example 2 (CEX2), the comparative example 3 (CEX3), and the comparative example 4 (CEX4) is greater than the slope of decrease in normalized luminance over time of the display device satisfying the REF. Here, a characteristic satisfying the REF is an ideal characteristic which the display device DD of the present disclosure should follow.

As a result, when the encapsulation layer TEE′ includes the intermediate layer TFE2 containing an organic acid, and the thickness TH of the first encapsulation layer TFE1 of the encapsulation layer TEE′ satisfies the range of about 50 angstroms (Å) to about 500 angstroms (Å), it can be confirmed the lifespan characteristics of the first, second, and third light emitting elements LED1, LED2, and LED3 included in the display device are similar to or higher than the lifespan characteristics of the REF.

Referring again to FIGS. 1, 2, 3, 4, 5, 6, 7, and 8, the display device DD according to embodiments of the present disclosure may include the light emitting elements LED1, LED2, and LED3 including a plurality of quantum dots, the encapsulation layer TFE, TFE′, and TFE″ arranged on the light-emitting elements LED1, LED2, and LED3, and the encapsulation substrate (e.g., the second substrate SUB2) arranged on the encapsulation layer TFE, TFE′, and TFE″ and including glass. The encapsulation layer TFE, TFE′, and TFE″ may include the first encapsulation layer TFE and TFE′ including an organic material and having the thickness TH ranging from about 50 angstroms (Å) to about 500 angstroms (Å), the intermediate layer TFE2 including both a polymer-based material and an organic acid, and the second encapsulation layer TFE3 including an inorganic material arranged sequentially. Alternatively, the encapsulation layer TFE″ may include the intermediate layer TFE21 including an organic acid and the organic encapsulation layer TFE22 including a polymer-based material sequentially arranged between the first encapsulation layer TFE1 and the second encapsulation layer TFE3. Accordingly, damage to the light emitting elements LED1, LED2, and LED3 may be minimized or reduced, and the lifespan characteristics of the light emitting elements LED1, LED2, and LED3 may be excellent.

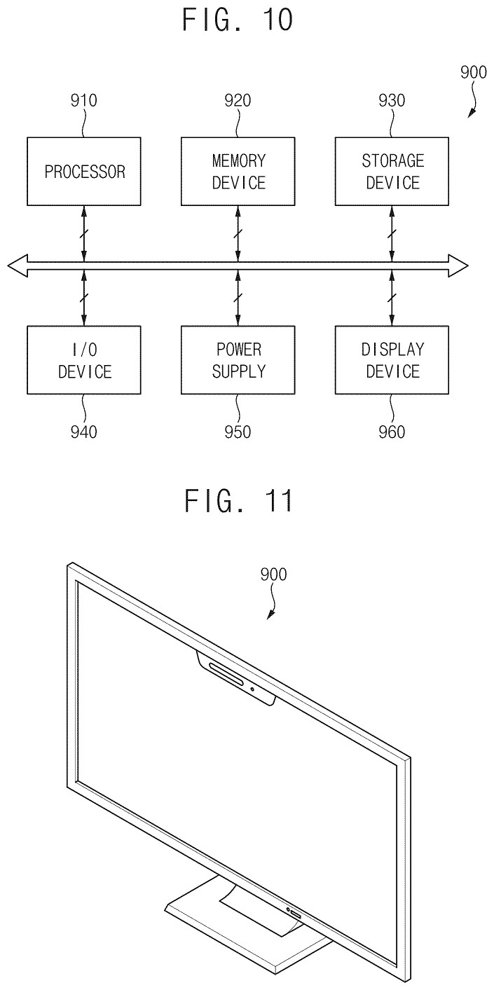

FIG. 10 is a block diagram showing an electronic device including the display device of FIG. 1. FIG. 11 is a view illustrating an example in which the electronic device of FIG. 10 is implemented as a television.

Referring to FIGS. 10 and 11, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1, 2, and 3. The electronic device 900 may further include several ports capable of communicating with a video card, a sound card, a memory card, a USB device, and the like.

In an embodiment, as shown in FIG. 11, the electronic device 900 may be implemented as a television. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. That is, the processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power for the operation of the electronic device 900. The display device 960 may be connected to other components through buses or other communication links. In an embodiment, the display device 960 may be included in the input/output device 940.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first substrate including a light emitting area and a non-light emitting area adjacent to the light emitting area;
a circuit layer arranged on the first substrate;
a light emitting element arranged in the light-emitting area on the circuit layer and including: a first electrode, a light emitting layer including quantum dots and arranged on the first electrode, and a second electrode arranged on the light emitting layer; and
an encapsulation layer arranged on the light emitting element and including:
a first encapsulation layer including an organic material;
an intermediate layer arranged on the first encapsulation layer including an organic acid; and
a second encapsulation layer arranged on the intermediate layer and including an inorganic material.

2. The display device of claim 1, wherein a thickness of the first encapsulation layer is in a range of about 50 angstroms (Å) to about 500 angstroms (Å).

3. The display device of claim 1, wherein the organic material of the first encapsulation layer includes at least one selected from a group consisting of silicone-based resin and acrylic-based resin.

4. The display device of claim 1, wherein the first encapsulation layer includes:
a first sub-layer including an organic material; and
a second sub-layer arranged on the first sub-layer and including an inorganic material.

5. The display device of claim 4, wherein the first sub-layer is arranged between the light emitting element and the second sub-layer, and the second sub-layer is arranged between the intermediate layer and the second encapsulation layer.

6. The display device of claim 4, wherein the inorganic material of the second sub-layer includes a silicon compound.

7. The display device of claim 1, wherein the intermediate layer further includes a polymer-based material.

8. The display device of claim 1, wherein the encapsulation layer further includes:
an organic encapsulation layer arranged between the intermediate layer and the second encapsulation layer and including a polymer-based material.

9. The display device of claim 1, wherein the organic acid of the intermediate layer includes at least one selected from a group consisting of polyacrylic acid (PAA), citric acid, isobutyric acid, and carboxylic acid.

10. The display device of claim 1, wherein the inorganic material of the second encapsulation layer includes a silicon compound.

11. The display device of claim 1, further comprising:
a second substrate, which is an encapsulation substrate arranged on the encapsulation layer and including glass.

12. The display device of claim 1, wherein the first electrode is an anode electrode, and the second electrode is a cathode electrode, and
wherein the light emitting element further includes:
a hole transport layer arranged between the first electrode and the light emitting layer;
a hole injection layer arranged between the first electrode and the hole transport layer; and
an electron transport layer arranged between the light emitting layer and the second electrode.

13. The display device of claim 12, wherein the electron transport layer includes inorganic particles including at least one selected from a group consisting of zinc oxide (ZnO) and zinc magnesium oxide (ZnMgO).

14. The display device of claim 1, wherein the first electrode is a cathode electrode, and the second electrode is an anode electrode, and
wherein the light emitting element further includes:
an electron transport layer arranged between the first electrode and the light emitting layer;
a hole transport layer arranged between the light emitting layer and the second electrode; and
a hole injection layer arranged between the light emitting layer and the hole transport layer.

15. The display device of claim 14, wherein the electron transport layer includes inorganic particles including at least one selected from a group consisting of ZnO and ZnMgO.

16. An electronic device comprising:
a display device;
a power supply which supplies power to the display device; and
a processor which controls the display device,
wherein the display device including:
a substrate including a light emitting area and a non-light emitting area adjacent to the light emitting area;
a circuit layer arranged on the substrate;
a light emitting element arranged in the light-emitting area on the circuit layer and including: a first electrode, a light emitting layer including quantum dots and arranged on the first electrode, and a second electrode arranged on the light emitting layer; and
an encapsulation layer arranged on the light emitting element and including:
a first encapsulation layer including an organic material;
an intermediate layer arranged on the first encapsulation layer including an organic acid; and
a second encapsulation layer arranged on the intermediate layer and including an inorganic material.

17. The electronic device of claim 16, wherein a thickness of the first encapsulation layer is in a range of about 50 angstroms (Å) to about 500 angstroms (Å).

18. The electronic device of claim 16, wherein the first encapsulation layer includes:
a first sub-layer including an organic material; and
a second sub-layer arranged on the first sub-layer and including an inorganic material, and
the first sub-layer is arranged between the light emitting element and the second sub-layer, and the second sub-layer is arranged between the intermediate layer and the second encapsulation layer.

19. The electronic device of claim 16, wherein the intermediate layer further includes a polymer-based material.

20. The electronic device of claim 16, wherein the encapsulation layer further includes:
an organic encapsulation layer arranged between the intermediate layer and the second encapsulation layer and including a polymer-based material.
